(19) United States
(12) Patent Application Publication
(10) Pub. No.: US 2026/0181995 A1
(43) Pub. Date: Jun. 25, 2026

(54) TRENCH CAPACITOR WITH BOTTOM BARRIER ELECTRODE

(71) Applicant: Taiwan Semiconductor Manufacturing Company, Ltd., Hsinchu (TW)

(72) Inventors: Guanyu Luo, Chiayi County (TW); Ming-Che Lee, Tainan City (TW); Che Wei Yang, New Taipei City (TW); Bi-Shen Lee, Hsinchu (TW); Sheng-Chau Chen, Tainan City (TW)

(21) Appl. No.: 18/991,936

(22) Filed: Dec. 23, 2024

(51) Int. Cl. H10D 80/20; H01L 23/522; H01L 23/532; H01L 25/18; H10D 1/00; H10D 1/68

(52) U.S. Cl. CPC H10D 80/215; H10D 1/042; H10D 1/716; H10W 20/496; H10W 90/00; H10W 20/4446

(57) ABSTRACT

An integrated chip including a first conductive interconnect, a dielectric structure, and a trench capacitor. The first conductive interconnect is over a semiconductor substrate. The dielectric structure includes a plurality of dielectric layers over the first conductive interconnect. The trench capacitor is over the dielectric structure and extends between sidewalls of the dielectric structure to the first conductive interconnect. The trench capacitor includes a bottom electrode layer, a top electrode layer over the bottom electrode layer, and a first insulator layer between the bottom electrode layer and the top electrode layer. A lower surface of the first insulator layer is between the sidewalls of the dielectric structure and spaced over an upper surface of the first conductive interconnect. The bottom electrode layer includes a first metal compound which extends from the lower surface of the first insulator layer to the upper surface of the first conductive interconnect.

### BACKGROUND

Many modern integrated chips include transistors as well as passive devices. Some examples of passive devices include capacitors, resistors, inductors, varactors, etc. Passive devices are widely used to control integrated chip characteristics, such as gains, time constants, etc. Some passive devices include integrated passive devices (IPDs). An IPD is a collection of one or more passive devices embedded into a single monolithic device and packaged as an integrated circuit (IC).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a trench capacitor.

FIG. 2 illustrates a cross-sectional view of some other embodiments of a trench capacitor.

FIG. 3 illustrates a cross-sectional view of some embodiments of an integrated chip including the trench capacitor of FIG. 1.

FIG. 4 illustrates a cross-sectional view of some embodiments of an integrated chip including the trench capacitor of FIG. 2.

FIG. 5 and FIG. 6 illustrate cross-sectional views of some embodiments of the trench capacitor of FIG. 1.

FIG. 7 and FIG. 8 illustrate cross-sectional views of some embodiments of the trench capacitor 120 of FIG. 2.

FIG. 9 and FIG. 12 illustrate cross-sectional views of some other embodiments of the trench capacitor of FIG. 1.

FIG. 10 and FIG. 13 illustrate cross-sectional views of some other embodiments of the trench capacitor of FIG. 2.

FIG. 11 illustrates a cross-sectional view of some embodiments of a portion of the bottom electrode layer of FIG. 9 and/or FIG. 10.

FIG. 14 illustrates a cross-sectional view of some embodiments of a portion of the bottom electrode layer of FIG. 12 and/or FIG. 13.

FIGS. 15-36 illustrate cross-sectional views of some embodiments of a method for forming an integrated chip including a trench capacitor.

FIG. 37 illustrates a flow diagram of some embodiments of a method for forming an integrated chip including a trench capacitor.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated chip includes a transistor along a semiconductor substrate. A conductive interconnect is over and coupled to the transistor. A dielectric structure including a plurality of dielectric layers is over the conductive interconnect. Sidewalls of the dielectric structure and an upper surface of the conductive interconnect form a trench. A trench capacitor is in the trench and on the conductive interconnect. The trench capacitor includes a bottom electrode layer coupled to the conductive interconnect, a top electrode layer spaced over the bottom electrode layer, and an insulator layer between the bottom electrode layer and the top electrode layer.

In some cases, when forming layers over the conductive interconnect, particles of the conductive interconnect can diffuse into the trench (to sidewalls of dielectric structure) or out of the top of the trench, which can be problematic. In some other cases, when forming layers over the conductive interconnect, oxidation may occur along the upper surface of the conductive (e.g., an oxide layer may form on the upper surface of the conductive interconnect between the conductive interconnect and the bottom electrode layer) which may increase a contact resistance between the conductive interconnect and the bottom electrode layer.

In some chips, a barrier layer is between sidewalls of the dielectric structure and the bottom electrode layer, and between the upper surface of the conductive interconnect and the bottom electrode layer. The barrier layer comprises a conductive material which serves as a barrier to diffusion and oxidation of the underlying conductive interconnect. However, the barrier layer may increase the cost of the trench capacitor and may increase the time needed to form the trench capacitor. Further, the barrier layer takes up substantial space in the trench. Thus, to accommodate the barrier layer, the size of the trench may need to be increased or the number of layers over the bottom electrode layer in the trench may need to be reduced.

In various embodiment of the present disclosure, the bottom electrode directly contacts the conductive interconnect (e.g., the trench capacitor is barrier-free). By removing the barrier layer, the trench capacitor cost and process time can be reduced. Further, removing the barrier layer, the size of the trench can be reduced, or additional layers can be added over the bottom electrode layer. For example, additional electrode layers can be formed in the trench without necessarily increasing the size of the trench. Thus, a capacitance of the trench capacitor can be increased without necessarily increasing the size of the trench.

The bottom electrode layer comprises a metal compound (e.g., a metal nitride or a metal oxide) having good diffusion blocking and good oxidation blocking properties. Thus, the bottom electrode layer can serve as a barrier as a barrier to diffusion and oxidation of the underlying conductive interconnect. Further, the metal compound of the bottom electrode layer has a high work function (e.g., greater than about 4.6 electron Volts (eV)). Thus, the bottom electrode layer may exhibit improved reliability and performance.

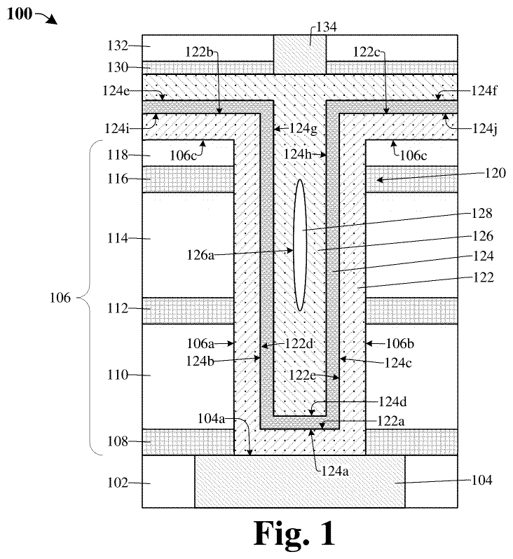

FIG. 1 illustrates a cross-sectional view 100 of some embodiments of a trench capacitor 120.

A conductive interconnect 104 (e.g., a conductive line, a conductive pad, or the like) is between sidewalls of a dielectric layer 102. A dielectric structure 106 is over the conductive interconnect 104. In some embodiments, the dielectric structure 106 includes dielectric etch stop layers 108, 112, 116 and interlayer dielectric layers 110, 114, 118. Sidewalls 106a, 106b of the dielectric structure 106 and an upper surface 104a of the conductive interconnect 104 form a trench (not labeled).

The trench capacitor 120 is over the dielectric structure 106 and in the trench. The trench capacitor 120 is on the conductive interconnect 104. The trench capacitor 120 includes a bottom electrode layer 122, a top electrode layer 126, and insulator layer 124 between the bottom electrode layer 122 and the top electrode layer 126. The bottom electrode layer 122 is on an upper surface 106c and sidewalls 106a, 106b of the dielectric structure 106 (e.g., an upper surface of dielectric layer 118 and sidewalls of dielectric layers 108, 110, 112, 114, 116, 118) and on an upper surface 104a of conductive interconnect 104. The first insulator layer 124 in on upper surfaces 122 a, 122 b, 122 c and sidewalls 122d, 122e of the bottom electrode layer 122. The top electrode layer 126 in on upper surfaces 124 d, 124 e, 124 f and sidewalls 124g, 124h of the first insulator layer 124. The top electrode layer 126 fills the remainder of the trench. In some embodiments, a cavity 128 is within the top electrode layer 126 between the sidewalls 106a, 106b of the dielectric structure 106 that partially delimit the trench. The cavity is delimited by one or more surfaces 126a of the top electrode layer 126.

A dielectric capping layer 130 is over the top electrode layer 126 and a dielectric layer 132 is over the dielectric capping layer 130. A conductive contact 134 extends through the dielectric layer 132 and the dielectric capping layer 130 to the top electrode layer 126.

The bottom electrode layer 122 comprises a first metal compound (e.g., a first metal nitride or a first metal oxide). The trench capacitor 120 is devoid of a barrier layer between the bottom electrode layer 122 and the conductive interconnect 104. Thus, the first metal compound of the bottom electrode layer 122 extends continuously from the first insulator layer 124 to the dielectric structure 106 and the conductive interconnect 104. For example, the first metal compound extends continuously from a lower surface 124a the first insulator layer 124 to the upper surface 104a of the conductive interconnect 104, from outer sidewalls 124b, 124c of the first insulator layer to the sidewalls 106a, 106b of the dielectric structure 106, and from lower surfaces 124i, 124j of the first insulator layer 124 to the upper surface 106c of the dielectric structure 106.

Because the trench capacitor 120 is devoid of a bottom electrode barrier layer (and instead the bottom electrode layer 122 directly contacts the dielectric structure 106 and the conductive interconnect 104), a cost of forming the trench capacitor 120 can be reduced and a process time for forming the trench capacitor 120 can be reduced.

Further, the first metal compound exhibits good diffusion blocking properties and good oxidation blocking properties. Thus, the bottom electrode layer 122 can block diffusion of atoms of the conductive interconnect 104 during the formation of overlying layers (e.g., during the formation of the bottom electrode layer 122, the first insulator layer 124, and the top electrode layer 126) and can help reduce oxidation at the interface between conductive interconnect 104 and the bottom electrode layer 122.

Furthermore, the first metal compound exhibits a high work function, which may help reduce current leakage in the trench capacitor. Thus, a reliability of the trench capacitor may be improved. Further, because the first metal compound has a high work function, the thickness of the first insulator layer 124 can be reduced and thus the capacitance of the trench capacitor 120 can be increased.

In some embodiments, because the bottom electrode layer 122 serves as both a bottom electrode and a barrier layer, the bottom electrode layer 122 may be referred to as a bottom barrier/electrode layer.

The top electrode layer 126 comprises a second metal compound (e.g., a second metal nitride or a second metal oxide). In some embodiments, the second metal compound exhibits good diffusion blocking properties, good oxidation blocking properties, and high work function to further improve a reliability and/or performance of the trench capacitor 120. For example, diffusion and/or oxidation can be further reduced, current leakage can be further reduced, and the capacitance of the trench capacitor can be further increased. In some embodiments, the second metal compound is the same as the first metal compound to reduce a process time of forming the trench capacitor.

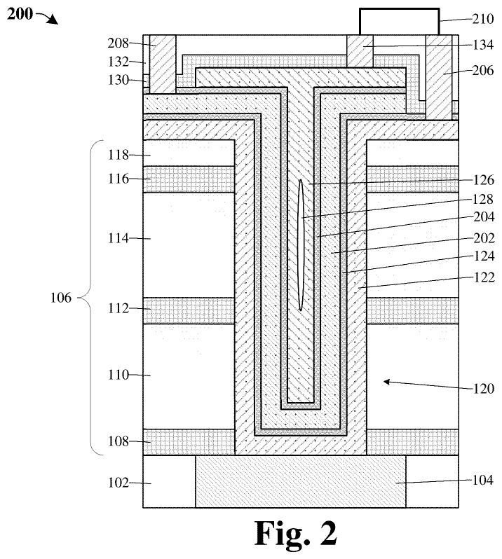

In addition, because the trench capacitor 120 does not include a barrier layer between the bottom electrode layer 122 and the conductive interconnect 104, additional electrode layers and insulator layers can be formed in the trench without necessarily increasing the size (e.g., width and/or depth) of the trench. For example, the trench capacitor 120 can further include a middle electrode layer 202 and a second insulator layer 204, as shown in cross-sectional view 200 of FIG. 2.

The middle electrode layer 202 is between the bottom electrode layer 122 and the top electrode layer 126. Conductive contact 134 is on and coupled to the top electrode layer 126. A conductive contact 206 is on and coupled to the bottom electrode layer 122. A conductive contact 208 is on and coupled to the middle electrode layer 202. Contact 206 is coupled to contact 134 (e.g., as illustrated by connection 210) to couple the bottom electrode layer 122 to the top electrode layer 126. Thus, the bottom electrode layer 122 and the top electrode layer 126 together form a first electrode of the trench capacitor 120. The middle electrode layer 202 is electrically isolated from the bottom electrode layer 122 and the top electrode layer 126. Thus, the middle electrode layer 202 and forms a second electrode of the trench capacitor 120. By coupling the bottom electrode layer to the top electrode layer 126, the total area between the two electrodes of the trench capacitor 120 can be increased and thus the capacitance of the trench capacitor 120 can be increased.

The middle electrode layer 202 comprises a third metal compound (e.g., a third metal nitride or a third metal oxide). In some embodiments, the third metal compound exhibits good diffusion blocking properties, good oxidation blocking properties, and high work function to further improve a reliability and/or performance of the trench capacitor 120. In some embodiments, the third metal compound is the same as the first metal compound and the second metal compound to reduce a process time of forming the trench capacitor.

In some embodiments, the metal compounds having “good” diffusion blocking properties and “good” oxidation blocking properties refers to the metal compounds having a sheet resistance after annealing that is less than a sheet resistance of titanium nitride after the same annealing. In some embodiments, the metal compounds having “good” diffusion blocking properties and “good” oxidation blocking properties refers to the metal compounds having a sheet resistance that is less than about 0.1 ohms per square after annealing at a temperature of about 600 degrees Celsius.

In some embodiments, the metal compounds having “high” work function refers to the metal compounds having work functions that are greater than a work function of titanium nitride. In some embodiments, the metal compounds having a “high” work function refers to the metal compounds having work functions that are greater than about 4.6 electron Volts (eV).

In some embodiments, the first metal compound is tungsten nitride, molybdenum nitride, or some other suitable material. In some other embodiments, the first metal compound is tungsten silicon nitride, molybdenum titanium oxide, molybdenum tantalum oxide, or some other suitable material.

In some embodiments, the second metal compound is tungsten nitride, molybdenum nitride, or some other suitable material. In some other embodiments, the second metal compound is tungsten silicon nitride, molybdenum titanium oxide, molybdenum tantalum oxide, or some other suitable material. In some other embodiments, the second metal compound is titanium nitride or some other suitable material.

In some embodiments, the third metal compound is tungsten nitride, molybdenum nitride, or some other suitable material. In some other embodiments, the third metal compound is tungsten silicon nitride, molybdenum titanium oxide, molybdenum tantalum oxide, or some other suitable material. In some other embodiments, the third metal compound is titanium nitride or some other suitable material.

In some embodiments, dielectric layers 102, 110, 114, 118, 132 comprise silicon dioxide or some other suitable material. In some embodiments, dielectric etch stop layers 108, 112, 116 and dielectric capping layer 130 comprise silicon nitride, silicon carbide, or some other suitable material. For example, in some embodiments, dielectric layers 108, 116 comprise silicon carbide and dielectric layers 112, 130 comprise silicon nitride. In some embodiments, the first insulator layer 124 comprises a high-k dielectric such as, for example, zirconium oxide, aluminum oxide, hafnium oxide, or some other suitable material. In some embodiments, conductive interconnect 104 and conductive contact 134 comprise copper, aluminum, or some other suitable material.

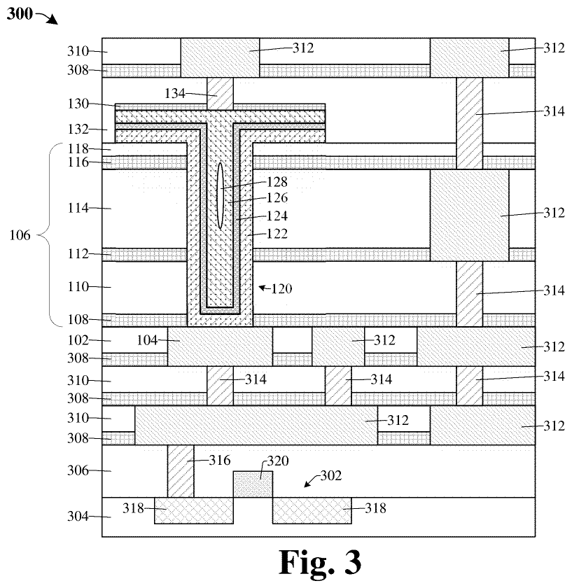

FIG. 3 illustrates a cross-sectional view 300 of some embodiments of an integrated chip including the trench capacitor 120 of FIG. 1. FIG. 4 illustrates a cross-sectional view 400 of some embodiments of an integrated chip including the trench capacitor 120 of FIG. 2.

Referring to FIG. 3 and FIG. 4, the integrated chip includes a transistor 302 along a semiconductor substrate 304. A plurality of dielectric layers (e.g., a contact dielectric layer 306, interlayer dielectric layers 310, 102, 110, 114, 118, and dielectric etch stop layers 308, 108, 112, 116) are over the semiconductor substrate 304. A plurality of conductive interconnects (e.g., conductive lines 312, conductive vias 314, and conductive contacts 316) are over the semiconductor substrate 304 and extend through the dielectric layers. The trench capacitor 120 is over the semiconductor substrate 304 and coupled to the transistor 302 by conductive interconnects. Conductive interconnects are over and coupled to the trench capacitor 120. In some embodiments (e.g., as illustrated in FIG. 4), a conductive line 312 couples contact 134 and contact 206 together.

In some embodiments, the transistor 302 comprises a pair of source/drains 318 and a gate 320. In some embodiments, the transistor 302 is a metal-oxide-semiconductor field-effect transistor (MOSFET), a junction field-effect transistor (JFET), a bipolar junction transistor (BJT), a fin field effect transistor (Fin FET), a gate-all-around field effect transistor (GAAFET), or some other suitable type of transistor.

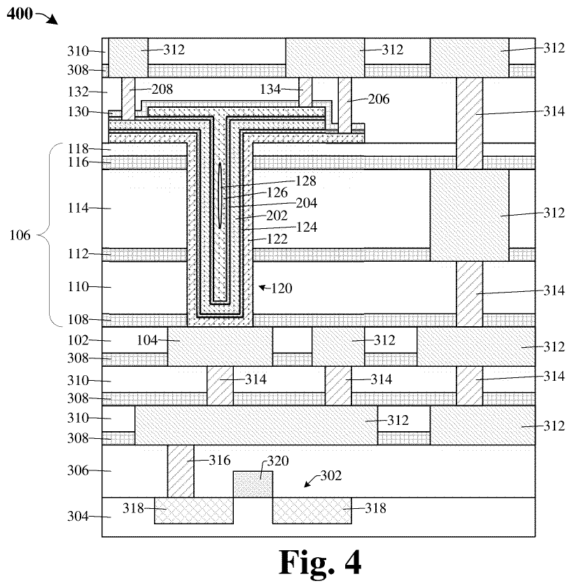

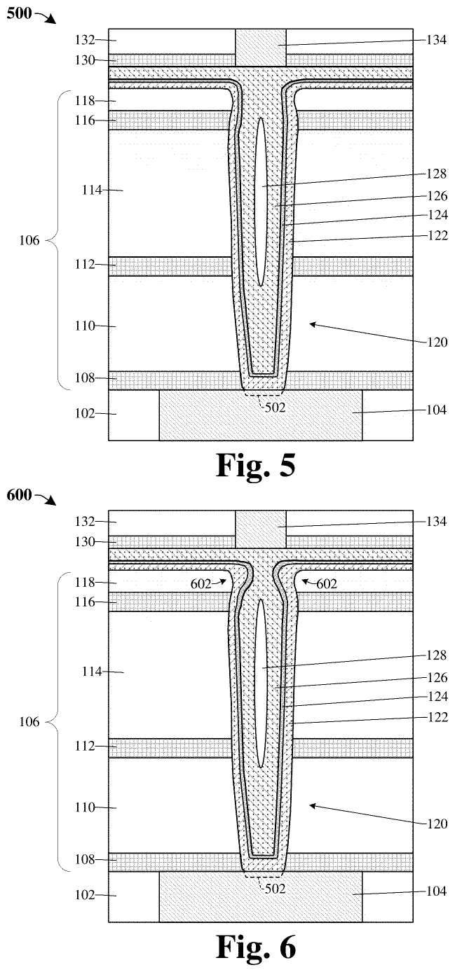

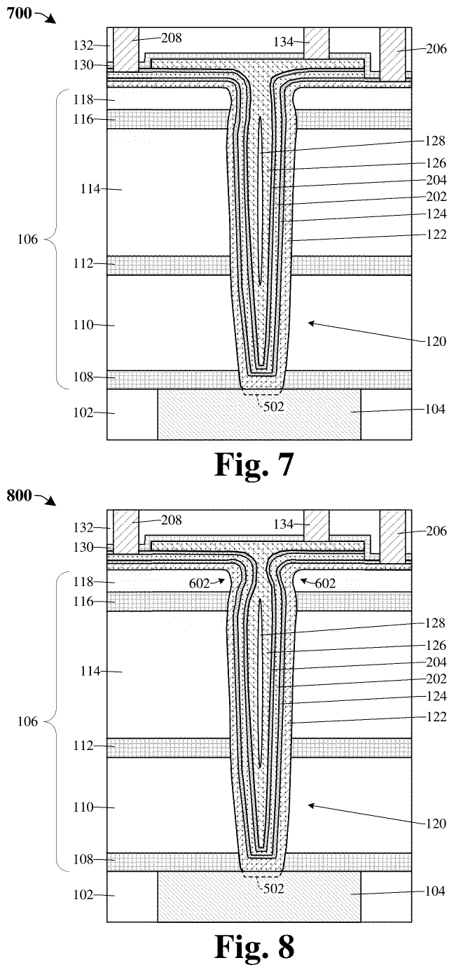

FIG. 5 illustrates a cross-sectional view 500 of some embodiments of the trench capacitor 120 of FIG. 1. FIG. 6 illustrates a cross-sectional view 600 of some other embodiments of the trench capacitor 120 of FIG. 1. FIG. 7 illustrates a cross-sectional view 700 of some embodiments of the trench capacitor 120 of FIG. 2. FIG. 8 illustrates a cross-sectional view 800 of some other embodiments of the trench capacitor 120 of FIG. 2.

Referring to FIGS. 5-8, the sidewalls of the dielectric structure 106 that delimit the trench are not planar. Further, in some embodiments, the thicknesses of the electrode layers 122, 126, 202 and the thicknesses of the insulator layers 124, 204 vary along the depth of the trench.

In some embodiments, the bottom electrode layer 122 extends into the conductive interconnect 104, as illustrated by dashed line 502. Thus, in such embodiments, the bottom electrode layer 122 is on an upper surface of conductive interconnect 104 that is below a topmost surface of conductive interconnective 104.

In some embodiments (as illustrated in FIGS. 6 and 8), the bottom electrode layer 122 has a “bulge” or an “overhang” structure 602 at the top of the trench which increases the thickness of the bottom electrode layer at the top of the trench. The overlying insulator layer(s) and electrode layer(s) conform to this “bulge” structure. Thus, the widths of the overlying layers may vary along the depth of the trench. For example, a width of the top electrode layer 126 is smaller along a top of the trench than along the middle of the trench.

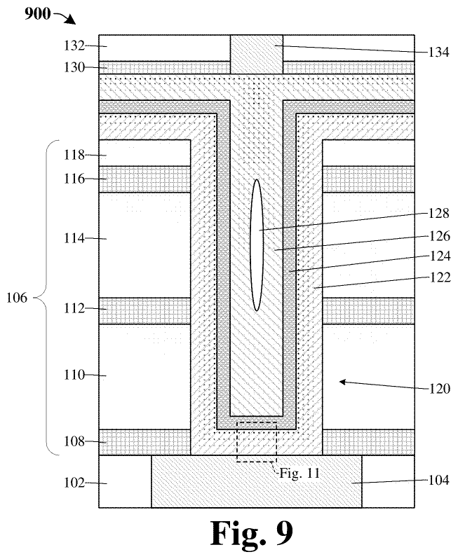

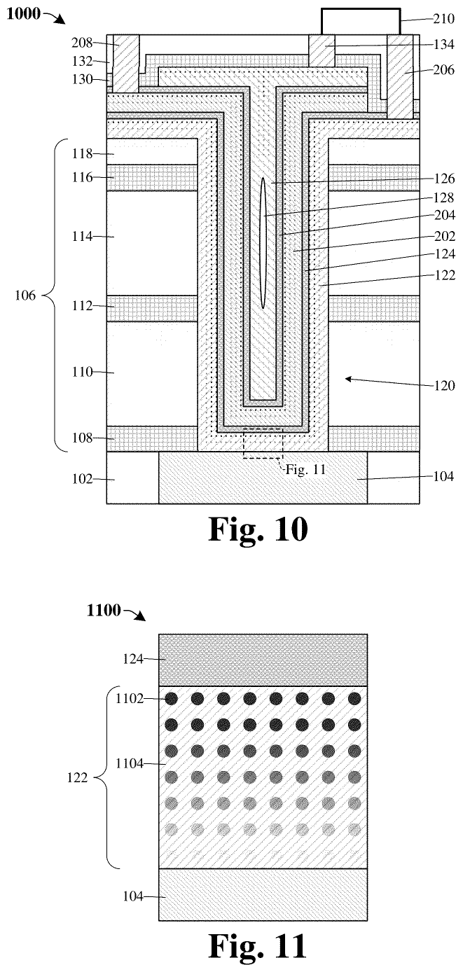

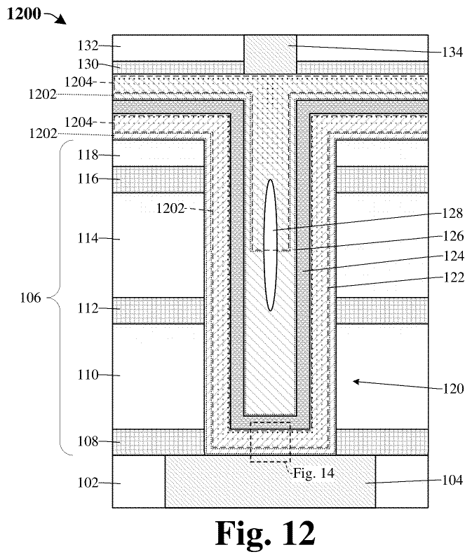

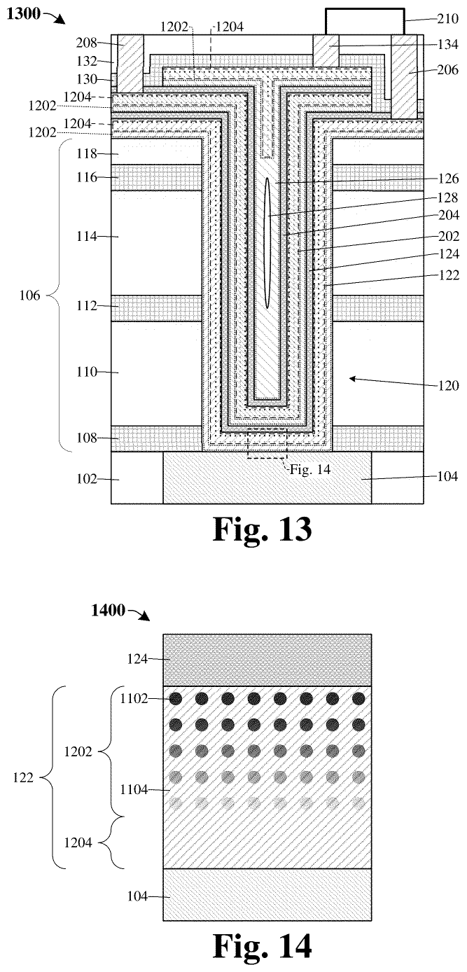

FIG. 9 and FIG. 12 illustrate cross-sectional views 900 and 1200, respectively, of some embodiments of the trench capacitor 120 of FIG. 1 in which the concentration of nitrogen or oxygen in the electrode layers exhibits a gradient. FIG. 10 and FIG. 13 illustrate cross-sectional views 1000 and 1300, respectively, of some embodiments of the trench capacitor 120 of FIG. 2 in which the concentration of nitrogen or oxygen in the electrode layers exhibits a gradient. FIG. 11 illustrates a cross-sectional view 1100 of some embodiments of a portion of the bottom electrode layer 122 of FIG. 9 and/or FIG. 10. FIG. 14 illustrates a cross-sectional view 1400 of some embodiments of a portion of the bottom electrode layer 122 of FIG. 12 and/or FIG. 13.

Referring to FIGS. 9-14, the concentration of nitrogen or oxygen in the bottom electrode layer 122 decreases from the first insulator layer 124 to the conductive interconnect 104 and the dielectric structure 106. In other words, the concentration of nitrogen or oxygen in the bottom electrode layer 122 is greater along first insulator layer 124 and decreases as the distance from the first insulator layer 124 increases and the distance from the conductive interconnect 104 or the dielectric structure 106 decreases. This is illustrated in FIGS. 9-14 by the gradient fill of the dots 1102 which symbolize nitrogen or oxygen atoms in the core metal 1104 (e.g., molybdenum or tungsten) of the bottom electrode layer 122. The increasing transparency of the dots 1102 symbolizes the decreasing concentration of the nitrogen or the oxygen (e.g., opaque dots 1102 symbolize higher nitrogen or oxygen concentration to the partially transparent dots 1102 symbolize lower nitrogen or oxygen concertation).

The nitrogen or oxygen concentration gradient is formed by diffusing nitrogen or oxygen atoms into a core metal (e.g., a metal precursor layer) from over the core metal. By forming the nitrogen or the oxygen gradient in the bottom electrode layer 122 so that the nitrogen concentration or the oxygen concentration is lower along the interface between the bottom electrode layer 122 and the conductive interconnect 104, a contact resistance between the bottom electrode layer 122 and the conductive interconnect 104 may be reduced. Further, by forming the nitrogen or the oxygen gradient in the bottom electrode layer 122 so that the nitrogen concentration or the oxygen concentration is higher along the interface between the bottom electrode layer 122 and the first insulator layer 124, the diffusion blocking properties of the bottom electrode may be increased along the first insulator layer 124. Thus, a performance and reliability of the trench capacitor 120 may be improved.

The middle electrode layer 202 (e.g., the metal compound of the middle electrode layer 202) follows a similar nitrogen or oxygen concentration gradient as the bottom electrode layer 122, as illustrated in FIG. 10. For example, the concentration of nitrogen or oxygen in the middle electrode layer 202 decreases from the second insulator layer 204 to the first insulator layer 124.

The top electrode layer 126 also exhibits a nitrogen or oxygen concentration gradient, as illustrated in FIGS. 9 and 10. For example, the top electrode layer 126 (e.g., the metal compound of the top electrode layer 126) has a higher nitrogen or oxygen concentration at the dielectric capping layer 130 and contact 134, and the top electrode layer 126 has a lower nitrogen or oxygen concentration as the distance from the dielectric capping layer 130 and contact 134 increases (e.g., as the top electrode layer 126 extends into the trench). In some embodiments, the nitrogen concentration or the oxygen concentration of the top electrode layer 126 may decrease substantially along the depth of the trench, as illustrated by the dot gradient in FIGS. 9 and 10.

In some embodiments (e.g., as illustrated in FIGS. 9-11), the electrode layers comprise nitrogen or oxygen throughout (e.g., from upper surfaces to lower surfaces and from inner sidewalls to outer sidewalls). For example, the metal compound of the bottom electrode layer 122 has a first non-zero nitrogen or oxygen concentration at a lower surface and outer sidewalls of the insulator layer 124, and the metal compound of the bottom electrode layer 122 has a second non-zero nitrogen or oxygen concentration, less than the first non-zero nitrogen or oxygen concentration, at an upper surface of the conductive interconnect 104 and sidewalls of the dielectric structure 106. Further, the nitrogen or oxygen concentration decreases gradually from the first non-zero nitrogen or oxygen concentration to the second non-zero nitrogen or oxygen concentration.

In some other embodiments (e.g., as illustrated in FIGS. 12-14), the electrode layers comprise diffusion regions 1202 in which the nitrogen concentration or the oxygen concentration of the metal compounds of those electrode layers decreases as the distance from the overlying layer increases, and the electrode layers further comprise core metal regions 1204 in which the nitrogen concentration or the oxygen concentration of the metal compounds is approximately zero (e.g., the core metal regions 1204 are approximately devoid of nitrogen or oxygen). These core metal regions 1204 of the electrode layers begin where the nitrogen or oxygen concentration gradient reaches approximately zero. For example, the metal compound of the bottom electrode layer 122 has a first non-zero nitrogen or oxygen concentration at a lower surface (and outer sidewalls) of the insulator layer 124, the metal compound of the bottom electrode layer 122 has a second non-zero nitrogen or oxygen concentration, less than the first non-zero nitrogen or oxygen concentration, at a location spaced between the lower surface of the insulator layer 124 an upper surface of the conductive interconnect 104 (and spaced between outer sidewalls of the insulator layer 124 and sidewalls of the dielectric structure 106), and the metal compound of the bottom electrode layer 122 has a third nitrogen or oxygen concentration, which is approximately equal to zero, at the upper surface of the conductive interconnect 104 (and at sidewalls of the dielectric structure 106).

By having approximately zero nitrogen or oxygen atoms in the bottom electrode layer 122 at the interface between the bottom electrode layer 122 and the conductive interconnect 104, the contact resistance between the bottom electrode layer 122 and the conductive interconnect 104 may be further reduced.

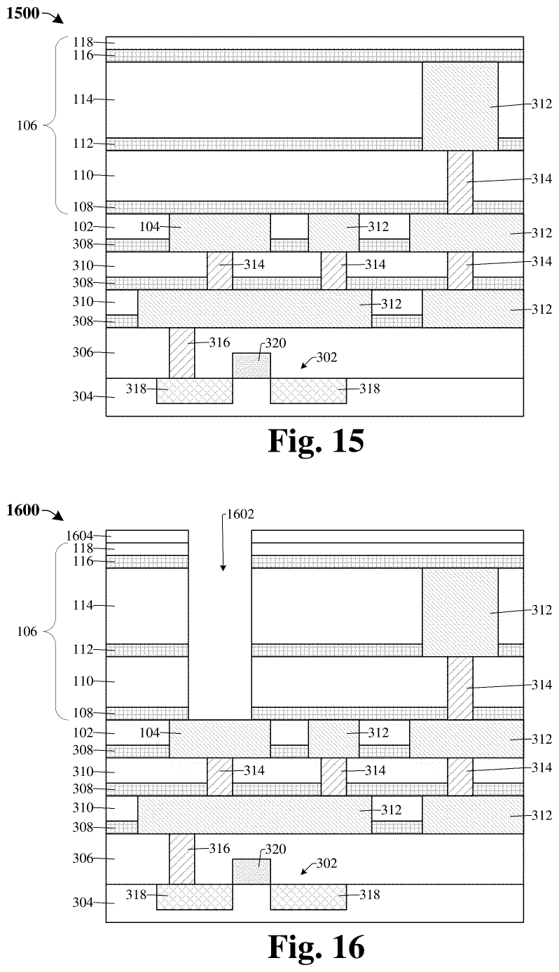

FIGS. 15-36 illustrate cross-sectional views 1500-3600 of some embodiments of a method for forming an integrated chip including a trench capacitor 120. Although FIGS. 15-36 are described in relation to a method, it will be appreciated that the structures disclosed in FIGS. 15-36 are not limited to such a method, but instead may stand alone as structures independent of the method.

As shown in cross-sectional view 1500 of FIG. 15, transistors are formed along a semiconductor substrate 304, a plurality of dielectric layers are formed over the semiconductor substrate 304, and a plurality of conductive interconnects are formed over the semiconductor substrate 304. For example, a transistor 302 is formed along the semiconductor substrate 304. A contact dielectric layer 306 and a contact 316 are formed over the transistor 302. Dielectric layers 310, 102, 110, 114, 118, dielectric etch stop layers 308, 108, 112, 116, conductive interconnect 104, conductive lines 312, and conductive vias 314 are formed over the contact dielectric layer 306 and the contact 316.

As shown in cross-sectional view 1600 of FIG. 16, the dielectric structure 106 (e.g., dielectric layers 118, 114, 110 and dielectric etch stop layers 116, 112, 108) is etched to form a trench 1602 in the dielectric structure 106 and to uncover an upper surface of conductive interconnect 104. The trench 1602 is delimited by sidewalls of the dielectric structure 106 and the upper surface of conductive interconnect 104. In some embodiments, a masking layer 1604 is formed over the dielectric structure 106 and the etching is performed according to the masking layer 1604. In some embodiments, the etching comprises a dry etching process (e.g., a plasma etching process, reactive ion etching process, an ion beam etching process, etc.) or some other suitable process. In some embodiments, the masking layer 1604 comprises photoresist, hard mask, or some other suitable material. In some embodiments, the etching extends slightly into conductive interconnect 104, forming a small depression (e.g., as shown in FIGS. 5-8) along the upper surface of the conductive interconnect 104.

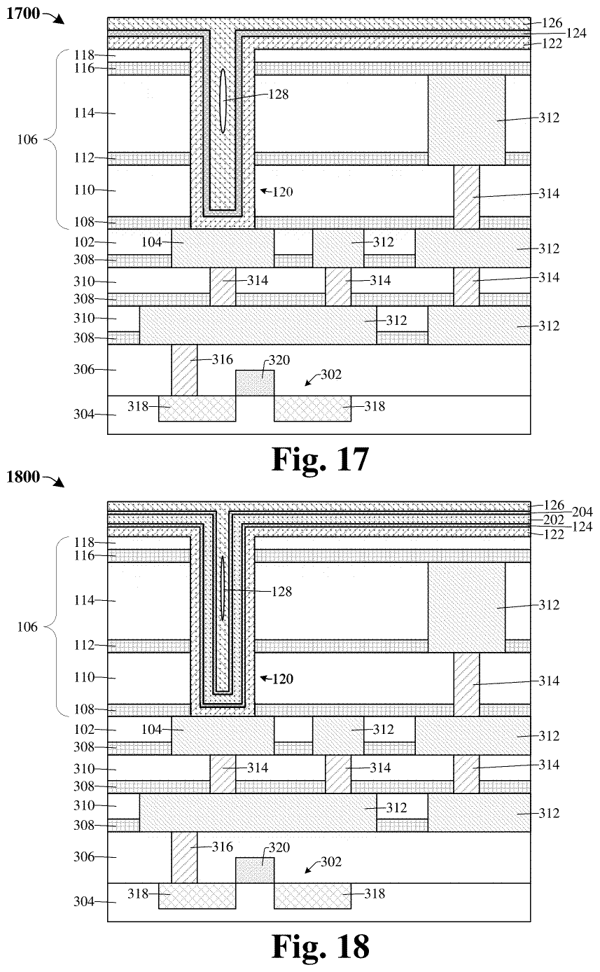

As shown in cross-sectional view 1700 of FIG. 17 and cross-sectional view 1800 of FIG. 18, the electrode layers and the insulator layer(s) are formed over the dielectric structure 106 and in the trench 1602. For example, the bottom electrode layer 122 is formed over the dielectric structure 106, in the trench 1602 (e.g., on sidewalls of the dielectric layers that delimit the trench 1602), and on conductive interconnect 104. The first insulator layer 124 is formed over the bottom electrode layer 122 (e.g., on sidewalls and upper surfaces of the bottom electrode layer 122) and in the trench 1602.

In some embodiments, the top electrode layer 126 is formed over the first insulator layer 124 (e.g., on sidewalls and upper surfaces of the first insulator layer 124) and in the trench 1602. In some other embodiments, a middle electrode layer 202 is formed over the first insulator layer 124 and in the trench 1602, a second insulator layer 204 is formed over the middle electrode layer 202 and in the trench 1602, and the top electrode layer 126 is formed over the second insulator layer 204 and in the trench 1602. In some embodiments, the top electrode layer 126 fills the trench 1602. In some embodiments, a cavity 128 remains within the top electrode layer 126. In some embodiments, the cavity 128 is filled with air.

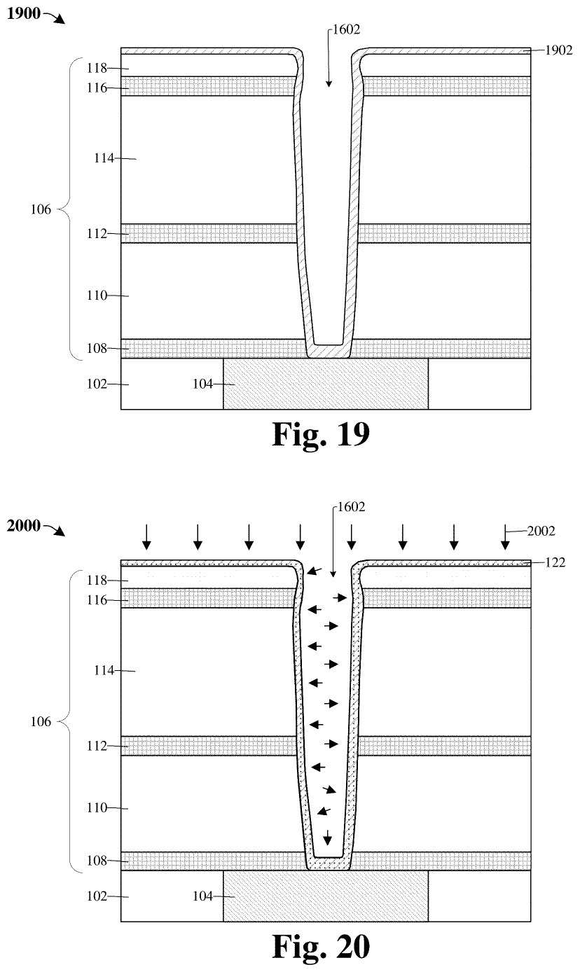

FIGS. 19-21 illustrate cross-sectional views 1900-2100 of some embodiments of a method for forming the bottom electrode layer 122 and the first insulator layer 124 over the dielectric structure 106 and in the trench 1602.

As shown in cross-sectional view 1900 of FIG. 19, a bottom electrode precursor layer 1902 is deposited on a top surface of dielectric layer 118, sidewalls of dielectric layer 118, sidewalls of dielectric etch stop layer 116, sidewalls of dielectric layer 114, sidewalls of dielectric etch stop layer 112, sidewalls of dielectric layer 110, sidewalls of dielectric etch stop layer 108, and an upper surface of conductive interconnect 104. In some embodiments, the bottom electrode precursor layer 1902 comprises tungsten, molybdenum, or some other suitable material. In some embodiments in which the bottom electrode precursor layer 1902 comprises tungsten, the bottom electrode precursor layer 1902 further comprises silicon, or some other suitable material. In some embodiments in which the bottom electrode precursor layer 1902 comprises molybdenum, the bottom electrode precursor layer 1902 further comprises tantalum, titanium, or some other suitable material. In some embodiments, the bottom electrode precursor layer 1902 is deposited by chemical vapor deposition (CVD) process, a physical vapor deposition (PVD) process, an atomic layer deposition (ALD) process, or some other suitable process.

In some embodiments, the bottom electrode precursor layer 1902 has a “bulge” or an “overhang” structure (e.g., an increased thickness) at the top of the trench 1602, as illustrated in FIG. 6 and FIG. 8. In some embodiments, the overhang can be increased by depositing the bottom electrode precursor layer 1902 with a PVD process. In some embodiments, the overhang can be reduced by depositing the bottom electrode precursor layer 1902 with an ALD process.

As shown in cross-sectional view 2000 of FIG. 20, in some embodiments, a nitriding process is performed to introduce nitrogen atoms into the bottom electrode precursor layer 1902, as illustrated by arrows 2002. The nitriding process forms the bottom electrode layer 122 from the bottom electrode precursor layer 1902 and the nitrogen atoms. Thus, in some embodiments, the bottom electrode layer 122 comprises tungsten nitride or molybdenum nitride. In some other embodiments, the bottom electrode layer 122 comprises tungsten silicon nitride. In some embodiments, the nitriding process comprises a plasma nitriding process which uses ammonia gas and plasma to diffuse nitrogen atoms into the bottom electrode precursor layer 1902. In some other embodiments, an oxidizing process is performed to introduce oxygen atoms into the bottom electrode precursor layer 1902. The oxidizing process forms the bottom electrode layer 122 from the bottom electrode precursor layer 1902 and the oxygen atoms. Thus, in some embodiments, the bottom electrode layer 122 comprises molybdenum titanium oxide, molybdenum tantalum oxide, or some other suitable material.

In some embodiments, the concentration of nitrogen (or oxygen) in the bottom electrode layer 122 exhibits a gradient, as shown in (and described with regard to) FIGS. 9-14. The gradient may be formed due to more nitrogen (or oxygen) atoms diffusing to shallower depths in the bottom electrode layer 122 and less nitrogen (or oxygen) atoms diffusing to deeper depths in the bottom electrode layer 122. This may be controlled by adjusting parameters (e.g., voltage, power, time, etc.) of the nitriding process (or the oxidizing process). The gradient may be formed to reduce the contact resistance between the bottom electrode layer 122 and the conductive interconnect 104.

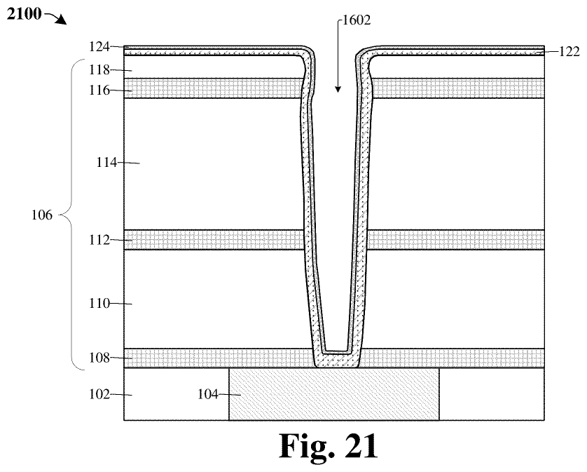

As shown in cross-sectional view 2100 of FIG. 21, the first insulator layer 124 is deposited on sidewalls upper surfaces of the bottom electrode layer 122 after the nitriding process (or the oxidizing process) is performed. In some embodiments, the first insulator layer 124 comprises zirconium oxide, aluminum oxide, hafnium oxide, or some other suitable material and is deposited by a CVD process, a PVD process, an ALD process, or some other suitable process.

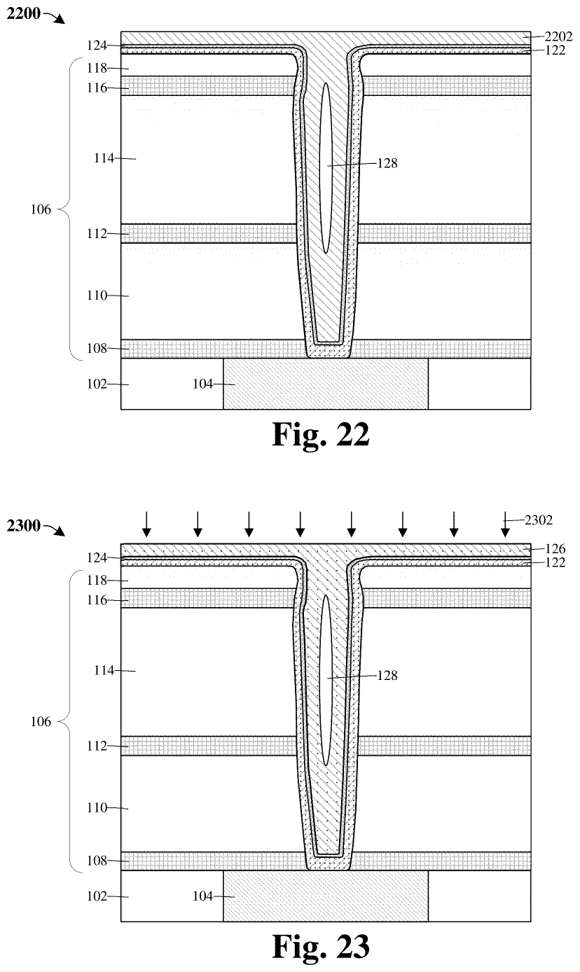

FIGS. 22-24 illustrate cross-sectional views 2200-2400 of some embodiments of a method for forming a remainder of the trench capacitor 120 over the first insulator layer 124.

As shown in cross-sectional view 2200 of FIG. 22, a top electrode precursor layer 2202 is deposited sidewalls and upper surfaces of the first insulator layer 124. In some embodiments, the top electrode precursor layer 2202 comprises tungsten, molybdenum, or some other suitable material. In some other embodiments, the top electrode precursor layer 2202 comprises titanium or some other suitable metal. In some embodiments in which the top electrode precursor layer 2202 comprises tungsten, the top electrode precursor layer 2202 further comprises silicon or some other suitable material. In some embodiments in which the top electrode precursor layer 2202 comprises molybdenum, the top electrode precursor layer 2202 further comprises titanium, tantalum, or some other suitable material. In some embodiments, the top electrode precursor layer 2202 is deposited by a CVD process, a PVD process, an ALD process, or some other suitable process.

In some embodiments, a cavity 128 remains in the trench 1602 within the top electrode precursor layer 2202. In some embodiments, the size of the cavity 128 can be increased by depositing the top electrode precursor layer 2202 with a PVD process. In some embodiments, the size of the cavity 128 can be reduced by depositing the top electrode precursor layer 2202 with an ALD process. In some embodiments, the cavity 128 is filled with air or the like.

As shown in cross-sectional view 2300 of FIG. 23, in some embodiments, a nitriding process is performed to introduce nitrogen atoms into the top electrode precursor layer 2202, as illustrated by arrows 2302. The nitriding process forms the top electrode layer 126 from the top electrode precursor layer 2202 and the nitrogen atoms. Thus, in some embodiments, the top electrode layer 126 comprises tungsten nitride or molybdenum nitride. In some other embodiments, the top electrode layer 126 comprises tungsten silicon nitride. In some other embodiments, the top electrode layer 126 comprises titanium nitride or some other suitable material. In some embodiments, the nitriding process comprises a plasma nitriding process. In some other embodiments, an oxidizing process is performed to introduce oxygen atoms into the top electrode precursor layer 2202. The oxidizing process forms the top electrode layer 126 from the top electrode precursor layer 2202 and the oxygen atoms. Thus, in some embodiments, the top electrode layer 126 comprises molybdenum titanium oxide, molybdenum tantalum oxide, or some other suitable material. In some embodiments, the concentration of nitrogen (or oxygen) in the top electrode layer 126 exhibits a gradient, as shown in (and described with regard to) FIGS. 9-14.

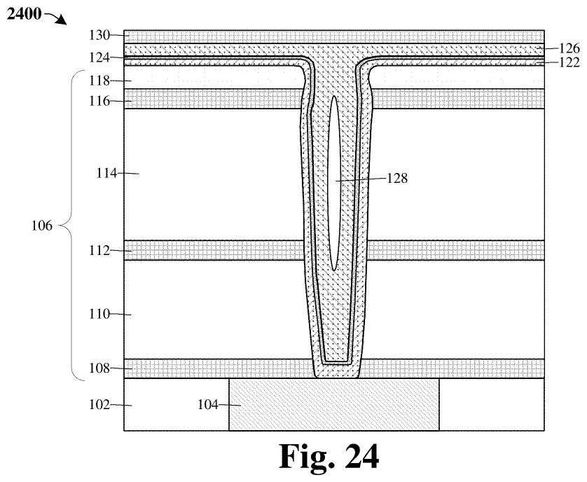

As shown in cross-sectional view 2400 of FIG. 24, a dielectric caping layer 130 is deposited on the top electrode layer 126. In some embodiments, the dielectric capping layer 130 comprises silicon nitride or some other suitable material and is deposited by a CVD process, a PVD process, an ALD process, or some other suitable process.

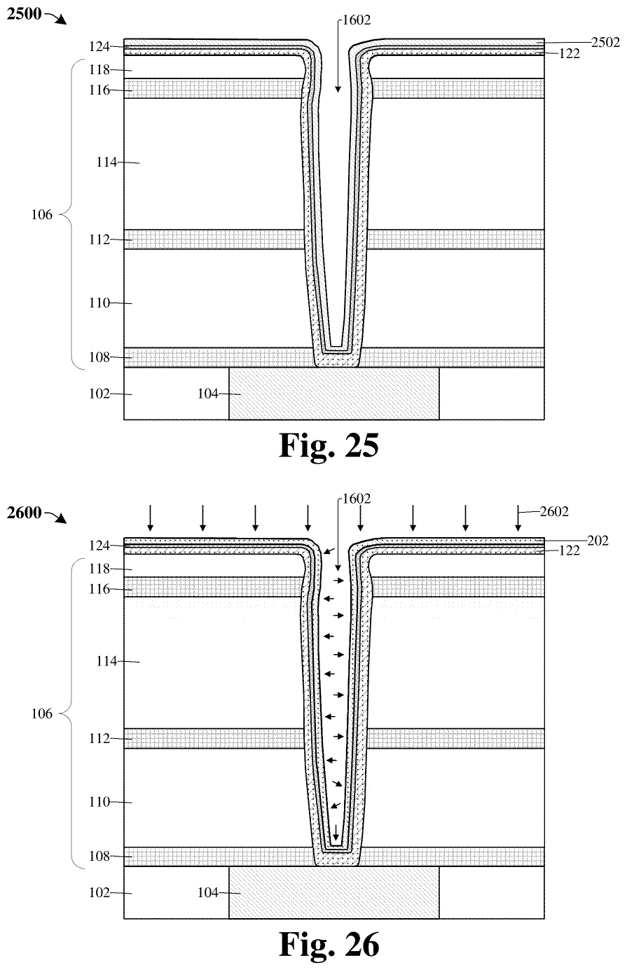

FIGS. 25-32 illustrate cross-sectional views 2500-3200 of some other embodiments of a method for forming a remainder of the trench capacitor 120 over the first insulator layer 124.

As shown in cross-sectional view 2500 of FIG. 25, a middle electrode precursor layer 2502 is deposited sidewalls and upper surfaces of the first insulator layer 124. In some embodiments, the middle electrode precursor layer 2502 comprises tungsten, molybdenum, or some other suitable material. In some other embodiments, the middle electrode precursor layer 2502 comprises titanium or some other suitable metal. In some embodiments in which the middle electrode precursor layer 2502 comprises tungsten, the middle electrode precursor layer 2502 further comprises silicon or some other suitable material. In some embodiments in which the middle electrode precursor layer 2502 comprises molybdenum, the middle electrode precursor layer 2502 further comprises titanium, tantalum, or some other suitable material. In some embodiments, the middle electrode precursor layer 2502 is deposited by a CVD process, a PVD process, an ALD process, or some other suitable process.

As shown in cross-sectional view 2600 of FIG. 26, in some embodiments, a nitriding process is performed to introduce nitrogen atoms into the middle electrode precursor layer 2502, as illustrated by arrows 2602. The nitriding process forms the middle electrode layer 202 from the middle electrode precursor layer 2502 and the nitrogen atoms. Thus, in some embodiments, the middle electrode layer 202 comprises tungsten nitride or molybdenum nitride. In some other embodiments, the middle electrode layer 202 comprises tungsten silicon nitride, molybdenum titanium oxide, or molybdenum tantalum oxide. In some other embodiments, the middle electrode layer 202 comprises titanium nitride or some other suitable material. In some embodiments, the nitriding process comprises a plasma nitriding process. In some other embodiments, an oxidizing process is performed to introduce oxygen atoms into the middle electrode precursor layer 2502. The oxidizing process forms the middle electrode layer 202 from the middle electrode precursor layer 2502 and the oxygen atoms. Thus, in some embodiments, the middle electrode layer 202 comprises molybdenum titanium oxide, molybdenum tantalum oxide, or some other suitable material. In some embodiments, the concentration of nitrogen (or oxygen) in the middle electrode layer 202 exhibits a gradient, as shown in (and described with regard to) FIGS. 9-14.

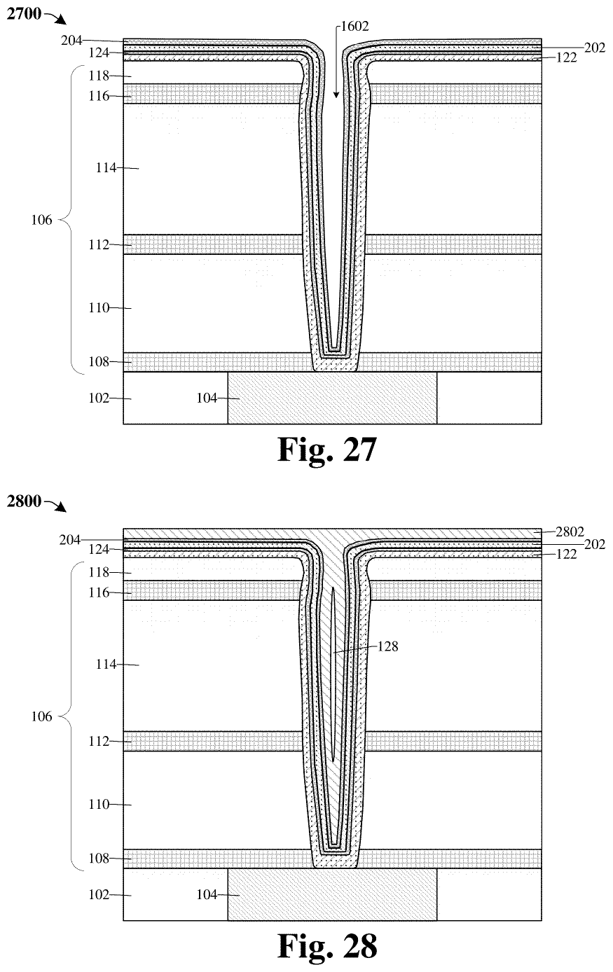

As shown in cross-sectional view 2700 of FIG. 27, a second insulator layer 204 is deposited on sidewalls upper surfaces of the middle electrode layer 202 after the nitriding process (or the oxidizing process) is performed on the middle electrode layer 202. In some embodiments, the second insulator layer 204 comprises zirconium oxide, aluminum oxide, hafnium oxide, or some other suitable material and is deposited by a CVD process, a PVD process, an ALD process, or some other suitable process.

As shown in cross-sectional view 2800 of FIG. 28, a top electrode precursor layer 2802 is deposited sidewalls and upper surfaces of the second insulator layer 204. In some embodiments, the top electrode precursor layer 2802 comprises tungsten, molybdenum, or some other suitable material. In some other embodiments, the top electrode precursor layer 2802 comprises titanium or some other suitable metal. In some embodiments in which the top electrode precursor layer 2802 comprises tungsten, the top electrode precursor layer 2802 further comprises silicon or some other suitable material. In some embodiments in which the top electrode precursor layer 2802 comprises molybdenum, the top electrode precursor layer 2802 further comprises titanium, tantalum, or some other suitable material. In some embodiments, the top electrode precursor layer 2802 is deposited by a CVD process, a PVD process, an ALD process, or some other suitable process.

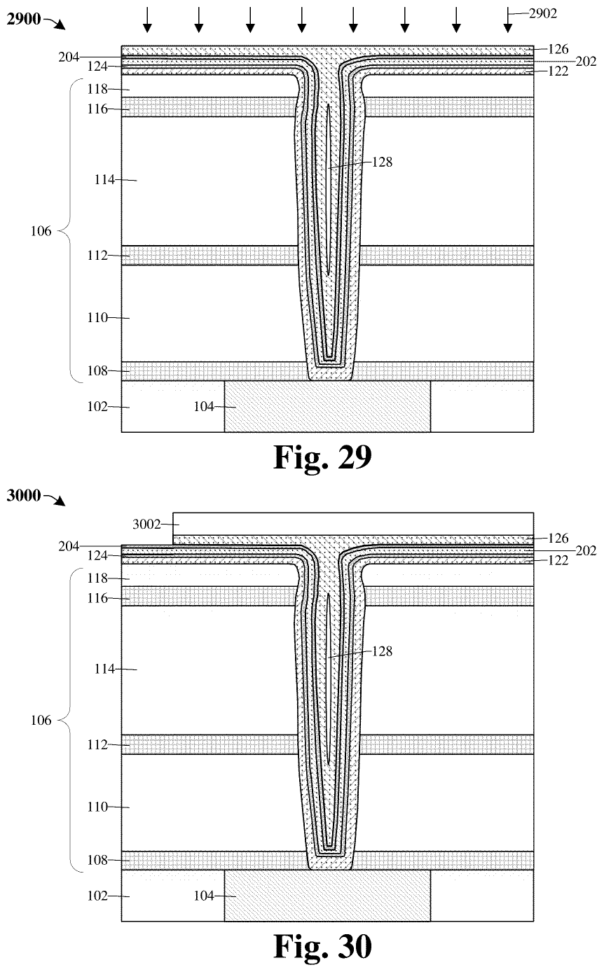

As shown in cross-sectional view 2900 of FIG. 29, in some embodiments, a nitriding process is performed to introduce nitrogen atoms into the top electrode precursor layer 2802, as illustrated by arrows 2902. The nitriding process forms the top electrode layer 126 from the top electrode precursor layer 2802 and the nitrogen atoms. Thus, in some embodiments, the top electrode layer 126 comprises tungsten nitride or molybdenum nitride. In some other embodiments, the top electrode layer 126 comprises tungsten silicon nitride, molybdenum titanium oxide, or molybdenum tantalum oxide. In some other embodiments, the top electrode layer 126 comprises titanium nitride or some other suitable material. In some embodiments, the nitriding process comprises a plasma nitriding process. In some other embodiments, an oxidizing process is performed to introduce oxygen atoms into the top electrode precursor layer 2802. The oxidizing process forms the top electrode layer 126 from the top electrode precursor layer 2802 and the oxygen atoms. Thus, in some embodiments, the top electrode layer 126 comprises molybdenum titanium oxide, molybdenum tantalum oxide, or some other suitable material. In some embodiments, the concentration of nitrogen (or oxygen) in the top electrode layer 126 exhibits a gradient, as shown in (and described with regard to) FIGS. 9-14.

As shown in cross-sectional view 3000 of FIG. 30, the top electrode layer 126 is etched to uncover a portion of the second insulator layer 204 (or a portion of the middle electrode layer 202). In some embodiments, a masking layer 3002 is formed over the dielectric structure 106 and the etching is performed according to the masking layer 3002. In some embodiments, the etching comprises a dry etching process or some other suitable process.

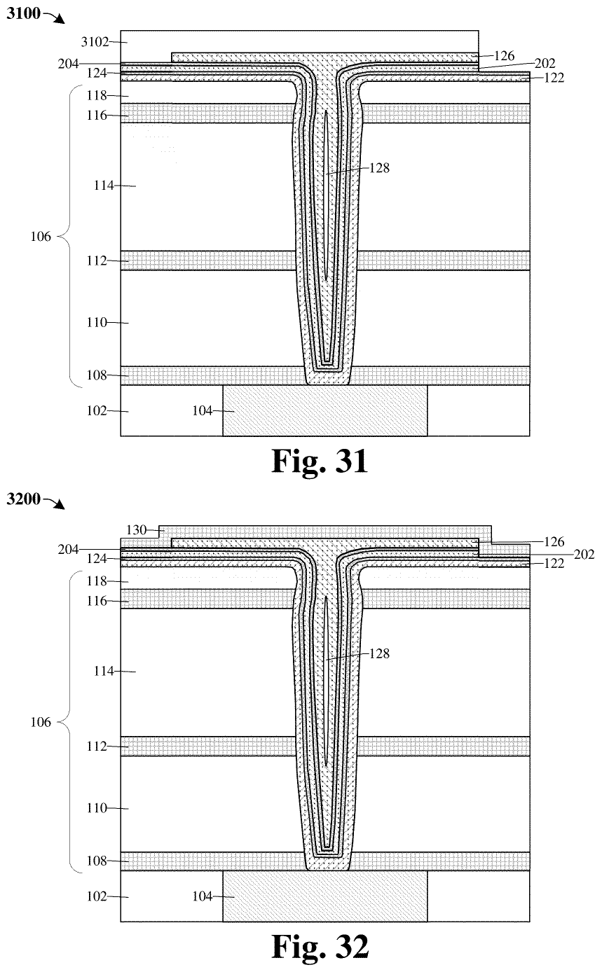

As shown in cross-sectional view 3100 of FIG. 31, the top electrode layer 126, the second insulator layer 204, and the middle electrode layer 202 are etched to uncover a portion of the first insulator layer 124 (or a portion of the bottom electrode layer 122). In some embodiments, a masking layer 3102 is formed over the dielectric structure 106 and the etching is performed according to the masking layer 3102. In some embodiments, the etching comprises a dry etching process or some other suitable process.

As shown in cross-sectional view 3200 of FIG. 32, a dielectric caping layer 130 is deposited on the top electrode layer 126, the second insulator layer 204, and the first insulator layer 124. In some embodiments, the dielectric capping layer 130 comprises silicon nitride or some other suitable material and is deposited by a CVD process, a PVD process, an ALD process, or some other suitable process.

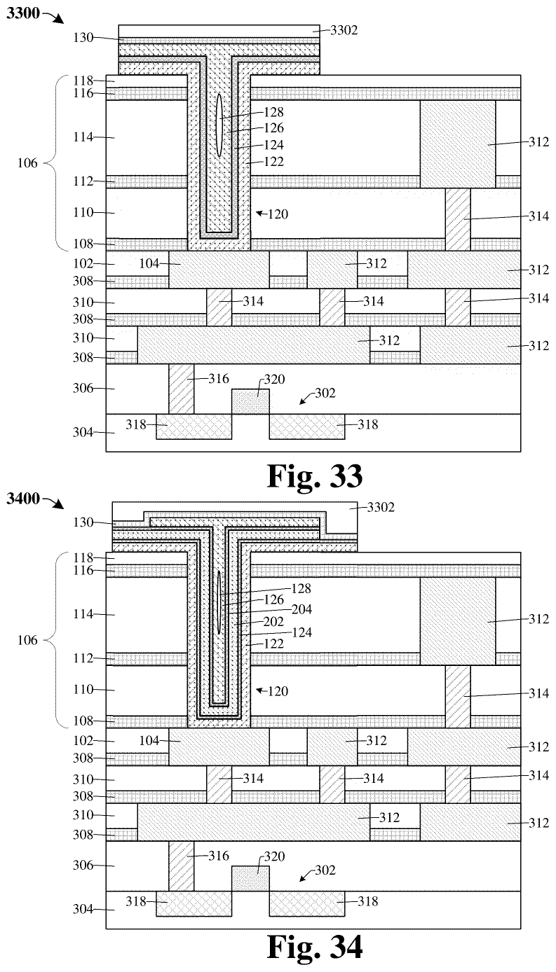

As shown in cross-sectional view 3300 of FIG. 33 and cross-sectional view 3400 of FIG. 34, the dielectric capping layer 130, the electrode layers, and the insulator layer(s) are etched to delimit the trench capacitor 120. In some embodiments, a masking layer 3302 is formed over the dielectric capping layer 130 and the etching is performed according to the masking layer 3302. In some embodiments, the etching comprises a dry etching process or some other suitable process.

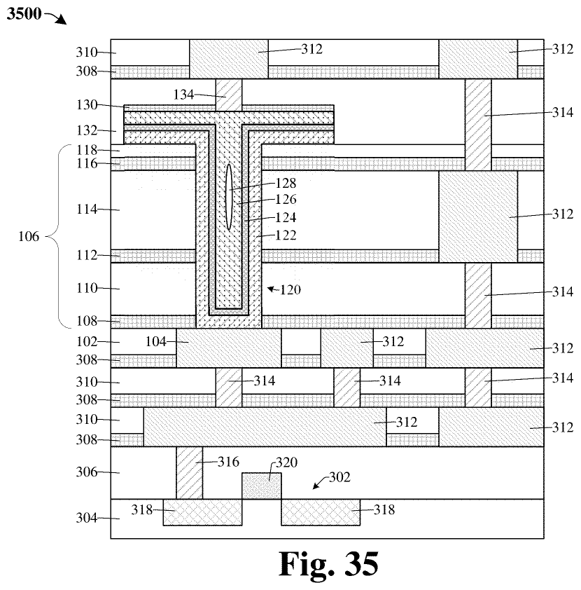

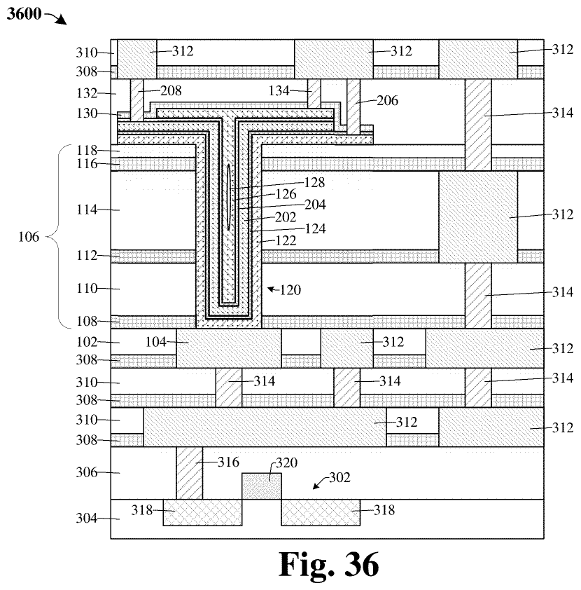

As shown in cross-sectional view 3500 of FIG. 35 and cross-sectional view 3600 of FIG. 36, conductive interconnects and dielectric layers are formed over the trench capacitor 120. For example, a dielectric layer 130 is deposited over the trench capacitor 120 and dielectric layer 118, Further, a dielectric etch stop layer 308 and a dielectric layer 310 are deposited over dielectric layer 130. A conductive vias 314 is formed laterally spaced from the trench capacitor 120. A contact 134 is formed on the top electrode layer 126. In some embodiments, a contact 206 is formed on the bottom electrode layer 122 and a contact 208 is formed on the middle electrode layer 202. Conductive lines 312 are formed over conductive vias 314 and contacts 134, 206, 208. In some embodiments (e.g., as illustrated in FIG. 36), one conductive line 312 is formed on both contact 134 and contact 206 to couple contact 134 to contact 206.

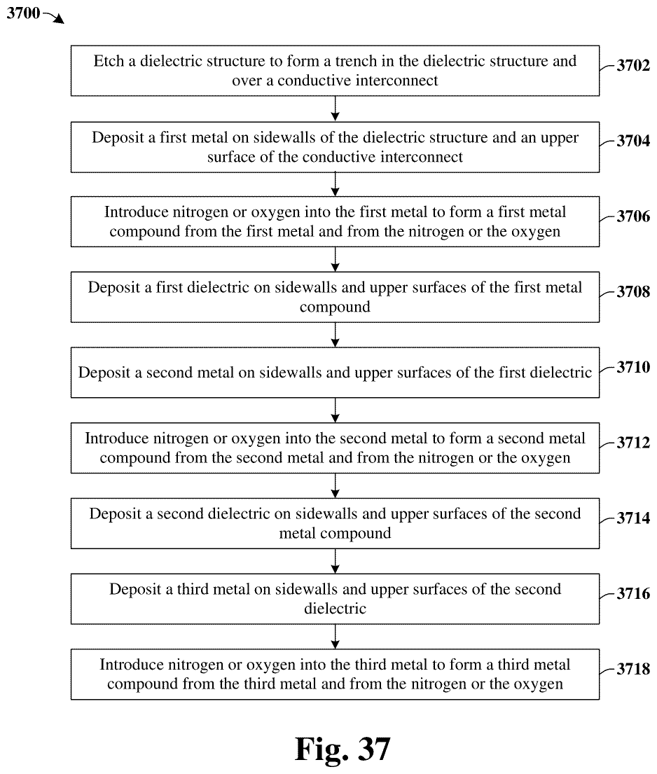

FIG. 37 illustrates a flow diagram of some embodiments of a method 3700 for forming an integrated chip including a trench capacitor. While method 3700 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 3702, etch a dielectric structure to form a trench in the dielectric structure and over a conductive interconnect. FIG. 16 illustrates a cross-sectional view 1600 of some embodiments corresponding to block 3702.

At block 3704, deposit a first metal on sidewalls of the dielectric structure and an upper surface of the conductive interconnect. In some embodiments, the first metal is molybdenum or tungsten. FIG. 19 illustrates a cross-sectional view 1900 of some embodiments corresponding to block 3704.

At block 3706, introduce nitrogen or oxygen into the first metal to form a first metal compound from the first metal and from the nitrogen or the oxygen. FIG. 20 illustrates a cross-sectional view 2000 of some embodiments corresponding to block 3706.

At block 3708, deposit a first dielectric on sidewalls and upper surfaces of the first metal compound. FIG. 21 illustrates a cross-sectional view 2100 of some embodiments corresponding to block 3708.

At block 3710, deposit a second metal on sidewalls and upper surfaces of the first dielectric. FIG. 22 illustrates a cross-sectional view 2200 of some embodiments corresponding to block 3710. FIG. 25 illustrates a cross-sectional view 2500 of some other embodiments corresponding to block 3710.

At block 3712, introduce nitrogen or oxygen into the second metal to form a second metal compound from the second metal and from the nitrogen or the oxygen. FIG. 23 illustrates a cross-sectional view 2300 of some embodiments corresponding to block 3712. FIG. 26 illustrates a cross-sectional view 2600 of some other embodiments corresponding to block 3712. In some embodiments, the method continues to block 3714.

At block 3714, deposit a second dielectric on sidewalls and upper surfaces of the second metal compound. FIG. 27 illustrates a cross-sectional view 2700 of some embodiments corresponding to block 3714.

At block 3716, deposit a third metal on sidewalls and upper surfaces of the second dielectric. FIG. 28 illustrates a cross-sectional view 2800 of some embodiments corresponding to block 3716.

At block 3718, introduce nitrogen or oxygen into the third metal to form a third metal compound from the third metal and from the nitrogen or the oxygen. FIG. 29 illustrates a cross-sectional view 2900 of some embodiments corresponding to block 3718.

Thus, the present disclosure relates to an integrated chip and a method for forming the integrated chip, the integrated chip including a trench capacitor, the trench capacitor including a bottom barrier/electrode layer on a conductive interconnect.

Accordingly, in some embodiments, the present disclosure relates to an integrated chip including a first conductive interconnect, a dielectric structure, and a trench structure. The first conductive interconnect is over a semiconductor substrate. The dielectric structure includes a plurality of dielectric layers over the first conductive interconnect. The trench structure is over the dielectric structure and extends between sidewalls of the dielectric structure to the first conductive interconnect. The trench structure includes a bottom electrode layer, a top electrode layer over the bottom electrode layer, and a first insulator layer between the bottom electrode layer and the top electrode layer. A lower surface of the first insulator layer is between the sidewalls of the dielectric structure and spaced over an upper surface of the first conductive interconnect. The bottom electrode layer includes a first metal compound which extends from the lower surface of the first insulator layer to the upper surface of the first conductive interconnect.

In other embodiments, the present disclosure relates to an integrated chip including a semiconductor substrate, a transistor, a first conductive interconnect, a dielectric structure, a first electrode layer, a first insulator layer, and a second electrode layer. The transistor is along the semiconductor substrate. The first conductive interconnect is over and coupled to the transistor. The dielectric structure includes a plurality of dielectric layers over the first conductive interconnect. The first electrode layer includes a first metal compound on an upper surface of the dielectric structure, a first sidewall of the dielectric structure, a second sidewall of the dielectric structure, and an upper surface of the first conductive interconnect. The first insulator layer is on the first metal compound. The second electrode layer is on the first insulator layer. A work function of the first metal compound is greater than a work function of titanium nitride.

In yet other embodiments, the present disclosure relates to a method for forming an integrated chip. The method includes forming a semiconductor structure along a semiconductor substrate. The method includes forming a first conductive interconnect over and coupled to the transistor. The method includes depositing a plurality of dielectric layers over the first conductive interconnect to form a dielectric structure over the first conductive interconnect. The method includes etching the dielectric structure to form a trench in the dielectric structure. The trench is formed by sidewalls of the dielectric structure and an upper surface of the first conductive interconnect. The method includes depositing a first metal layer on the sidewalls of the dielectric structure and the upper surface of the first conductive interconnect. The method includes introducing nitrogen or oxygen to the first metal layer to form a first metal compound layer from the first metal layer and from the nitrogen or the oxygen. The method includes depositing a first dielectric layer on the first metal compound layer. The method includes depositing a second metal layer over the first dielectric layer. The method includes introducing or oxygen nitrogen to the second metal layer to form a second metal compound layer from the second metal layer and from the nitrogen or the oxygen. The first metal compound layer forms a first electrode of a trench capacitor. The first dielectric layer forms a first insulator layer of the trench capacitor. The second metal compound layer forms a second electrode of the trench capacitor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip comprising:
a first conductive interconnect over a semiconductor substrate;
a dielectric structure comprising a plurality of dielectric layers over the first conductive interconnect; and
a trench structure over the dielectric structure and extending between sidewalls of the dielectric structure to the first conductive interconnect, the trench structure comprising a bottom electrode layer, a top electrode layer over the bottom electrode layer, and a first insulator layer between the bottom electrode layer and the top electrode layer,
wherein a lower surface of the first insulator layer is between the sidewalls of the dielectric structure and spaced over an upper surface of the first conductive interconnect, and wherein the bottom electrode layer comprises a first metal compound which extends from the lower surface of the first insulator layer to the upper surface of the first conductive interconnect.

2. The integrated chip of claim 1, wherein a work function of the first metal compound is greater than a work function of titanium nitride.

3. The integrated chip of claim 2, wherein the top electrode layer comprises a second metal compound having a work function that is greater than the work function of titanium nitride.

4. The integrated chip of claim 1, wherein a sheet resistance of the first metal compound is less than a sheet resistance of titanium nitride.

5. The integrated chip of claim 4, wherein the top electrode layer comprises a second metal compound having a sheet resistance that is less than a sheet resistance of titanium nitride.

6. The integrated chip of claim 1, the trench structure further comprising a middle electrode layer and a second insulator layer, wherein the second insulator layer is between the first insulator layer and the top electrode layer, wherein the middle electrode layer is between the first insulator layer and the second insulator layer, and wherein the top electrode layer and the bottom electrode layer are electrically coupled together and electrically isolated from the middle electrode layer.

7. The integrated chip of claim 6, wherein the middle electrode layer comprises a second metal compound and the top electrode layer comprises a third metal compound, and wherein a work function of the first metal compound, a work function of the second metal compound, and a work function of the third metal compound are greater than a work function of titanium nitride.

8. The integrated chip of claim 1, wherein the first metal compound is a first metal nitride, and wherein the first metal nitride of the bottom electrode layer extends continuously from the lower surface of the first insulator layer to the upper surface of the first conductive interconnect, from a first outer sidewall of the first insulator layer to a first sidewall of the sidewalls of the dielectric structure, and from a second outer sidewall of the first insulator layer to a second sidewall of the sidewalls of the dielectric structure.

9. The integrated chip of claim 1, wherein the first metal compound is a first metal nitride having a first non-zero nitrogen concentration at the lower surface of the first insulator layer and a second non-zero nitrogen concentration, less than the first non-zero nitrogen concentration, at the upper surface of the first conductive interconnect.

10. The integrated chip of claim 1, wherein the first metal compound is a first metal nitride having a first non-zero nitrogen concentration at the lower surface of the first insulator layer, a second non-zero nitrogen concentration, less than the first non-zero nitrogen concentration, between the lower surface of the first insulator layer and the upper surface of the first conductive interconnect, and a third nitrogen concentration at the upper surface of the first conductive interconnect, and wherein the third nitrogen concentration is approximately zero.

11. An integrated chip comprising:
a semiconductor substrate;
a transistor along the semiconductor substrate;
a first conductive interconnect over and coupled to the transistor;
a dielectric structure comprising a plurality of dielectric layers over the first conductive interconnect;
a first electrode layer comprising a first metal compound on an upper surface of the dielectric structure, a first sidewall of the dielectric structure, a second sidewall of the dielectric structure, and an upper surface of the first conductive interconnect;
a first insulator layer on the first metal compound; and
a second electrode layer on the first insulator layer,
wherein a work function of the first metal compound is greater than a work function of titanium nitride.

12. The integrated chip of claim 11, wherein the second electrode layer comprises the first metal compound, the integrated chip further comprising:
a contact on the first metal compound of the second electrode layer.

13. The integrated chip of claim 11, wherein the second electrode layer comprises the first metal compound, the integrated chip further comprising:
a second insulator layer on the first metal compound of the second electrode layer;
a third electrode layer comprising the first metal compound on the second insulator layer; and
a contact on the first metal compound of the third electrode layer.

14. The integrated chip of claim 11, wherein the first metal compound layer comprises tungsten nitride or molybdenum nitride, and wherein a nitrogen concentration of the first metal compound decreases from the first insulator layer to the first conductive interconnect.

15. A method for forming an integrated chip, the method comprising:
forming a semiconductor structure along a semiconductor substrate;
forming a first conductive interconnect over and coupled to the transistor;
depositing a plurality of dielectric layers over the first conductive interconnect to form a dielectric structure over the first conductive interconnect;
etching the dielectric structure to form a trench in the dielectric structure, the trench formed by sidewalls of the dielectric structure and an upper surface of the first conductive interconnect;
depositing a first metal layer on the sidewalls of the dielectric structure and the upper surface of the first conductive interconnect;
introducing nitrogen or oxygen to the first metal layer to form a first metal compound layer from the first metal layer and from the nitrogen or the oxygen;
depositing a first dielectric layer on the first metal compound layer;
depositing a second metal layer over the first dielectric layer; and
introducing nitrogen or oxygen to the second metal layer to form a second metal compound layer from the second metal layer and from the nitrogen or the oxygen,
wherein the first metal compound layer forms a first electrode of a trench capacitor, the first dielectric layer forms a first insulator layer of the trench capacitor, and the second metal compound layer forms a second electrode of the trench capacitor.

16. The method of claim 15, further comprising:
depositing a second dielectric layer over the second metal compound layer;
depositing a third metal layer over the second dielectric layer; and
introducing nitrogen or oxygen to the third metal layer to form a third metal compound layer from the third metal layer and from the nitrogen or the oxygen,
wherein the second dielectric layer forms a second insulator layer of the trench capacitor, and the third metal compound layer forms a third electrode of the trench capacitor.

17. The method of claim 15, wherein introducing nitrogen to the first metal layer comprises diffusing nitrogen into the first metal layer to form the first metal compound layer, and wherein a nitrogen concentration of the first metal compound layer is greater at an interface between the first metal compound layer and the first dielectric layer than at an interface between the first metal compound layer and the first conductive interconnect.

18. The method of claim 17, wherein the nitrogen concentration of the first metal compound layer is greater than zero at the interface between the first metal compound layer and the first conductive interconnect.

19. The method of claim 17, wherein the first metal compound layer comprises a diffusion region along the interface between the first metal compound layer and the first dielectric layer, wherein the nitrogen concentration of the first metal compound layer in the diffusion region gradually decreases as a distance from the first dielectric layer increases, wherein the first metal compound layer comprises a core metal region along the interface between the first metal compound layer and the first conductive interconnect, and wherein the nitrogen concentration of the first metal compound layer in the core metal region is approximately zero.

20. The method of claim 15, wherein the first metal compound layer consists essentially of tungsten nitride or molybdenum nitride.
